(19) United States
(12) Patent Application Publication
(10) Pub. No.: US 2009/0096083 A1
(43) Pub. Date: Apr. 16, 2009

(54) Connecting structure for connecting at least one semiconductor component to a power semiconductor module

(75) Inventors: Karlheinz Augustin, Furth (DE); Christian Goebl, Numberg (DE)

Correspondence Address: COHEN, PONTANI, LIEBERMAN & PAVANE LLP, 551 FIFTH AVENUE, SUITE 1210, NEW YORK, NY, 10176, US

(73) Assignee: SEMIKRON Elektronik GmbH & Co. KG

(21) Appl. No.: 12/284,190

(22) Filed: Sep. 19, 2008

(30) Foreign Application Priority Data
Sep. 19, 2007 (DE) 10 2007 044 620.0

(51) Int. Cl. H01L 23/522; H01L 23/538

(52) U.S. Cl. 257/700; 257/E23.145

(57) ABSTRACT

A connecting structure comprising a connecting device for electrically conductive connection to at least one semiconductor component and a filler. The connecting device is a film composite comprising at least two electrical films with an insulating film therebetween. The electrically conductive films are inherently structured and thus form conductor tracks. At least one semiconductor component is assigned to at least one cutout in the respective conductive film, wherein the filler is situated between the connecting device and the assigned semiconductor component.

### BACKGROUND OF THE INVENTION

1. Field of the Invention

The invention is directed to a connecting structure, preferably for use in a compact power semiconductor module, that includes a connecting device configured as a layered film composite and providing an electrically conductive connection to at least one power semiconductor component and driver components, wherein a filler is provided between the power semiconductor component and a conductor track of the connecting device. p 2. Description of the Related Art

So-called “flip-chip mounting” is known for making contact with unpackaged semiconductor components, wherein a semiconductor component is connected directly, and without further connections, to an electrically conductive contact area towards the conductor tracks of a circuit carrier. The contact is typically made by means of contact knobs. The remaining volume between the power semiconductor component and the conductor track is filled with an insulating filler of low viscosity and is conventionally referred to as the “process of capillary underfilling”.

Additionally, in power semiconductor modules produced in this way, driver components and further electronic components are fixed to the connecting device by adhesive bonding, by way of example, and are electrically conductively connected by bonding with thin wires.

Similar known devices may be found for example, in U.S. Pat. Nos. 7,042,074 and 6,624,216 and United States Publication No. 2007/0102796.

U.S. Pat. No. 7,042,074 discloses a power semiconductor module comprising a connecting device configured as a film composite. This film composite comprises at least a first and a second electrically conductive film separated by an insulating film. At least one conductive film is inherently structured and thus forms conductor tracks which are electrically insulated from one another and on which, in turn, power semiconductor components are arranged as required. Furthermore, the conductive film has contact knobs by which the power semiconductor components are permanently and securely electrically connected to the conductive film by ultrasonic welding.

United States Publication No. 2007/0102796 discloses a similar power semiconductor module, wherein the second conductive film is likewise inherently structured and thus forms conductor tracks and driver components are preferably adhesively bonded thereto and electrically conductively connected by thin wire bonding. The insulating film lying between the conductive films includes a cutout at a location free of metal on both sides, through which cutout a flexible thin wire enables the electrical contact-making between the first and second conductive films at corresponding bonding locations.

U.S. Pat. No. 6,624,216 describes a method in which the remaining volume between a power semiconductor component and a first conductive film is provided with a filler for safety reasons. The filler is preferably a synthetic epoxy resin with which abrasive substances are admixed in order to lower the coefficient of thermal expansion so as to reduce the thermal cycling load that typically arises in power semiconductors. This technology is typically referred to as “underfill” or “capillary underfilling” in accordance with the prior art.

What is disadvantageous in this process is that the filler, during the process of underfilling, usually does not adhere uniformly to the conductive film and has, in principle, poorer adhesion properties with respect to the conductive film than with respect to the power semiconductor component.

What is furthermore disadvantageous is that power semiconductor components in any connecting device generally react stress-sensitively to mechanical forces. If such forces lead to defects on the power semiconductor components, in consequence the conductivity or insulation capability with respect to the power semiconductor component and the function of the power semiconductor module are lastingly impaired. This stress sensitivity can be reduced by capillary underfilling.

### SUMMARY OF THE INVENTION

It is an object of the invention to provide an arrangement of a connecting device configured as a film composite and comprising at least one semiconductor component, wherein the mode of operation of the filler between the power semiconductor component and the conductor tracks is improved by increasing the adhesion of the filler.

In context, the invention is used in an arrangement comprising a connecting device for electrically conductive connection to at least one semiconductor component that is to be arranged thereon and is to be connected in circuitry-conforming fashion and a filler. In such an arrangement, unpackaged power semiconductor elements are intended to be connected to one another and/or to conductor tracks of an electrically conductive film on which they are arranged. Furthermore, driver components and additional electronic components are to be connected. Likewise, the external connections of the load connections and of all the required control and auxiliary connections of the power semiconductor components are to be connected.

The connecting device is configured as a layered film composite comprising at least one insulating film disposed between two electrically conductive films. At least one of the conductive films is inherently structured and thus forms conductor tracks which are insulated from one another. The first film has contact devices to contact the power connection pads of the power semiconductor components, which are preferably configured as contact knobs and are connected cohesively or in a force-locking manner, preferably by ultrasonic welding. A second conductive film has contact areas aligned with the logic connection pads of the driver components, which are preferably connected cohesively by adhesive bonding connection and to further conductor tracks electrically conductively by thin wire bonding.

According to the invention, at least one, preferably cylindrical, cutout is introduced into the surface of at least one conductive film. The cutout has an area of at most 25 percent of the area of an assigned semiconductor component and is arranged at least partly in the region to be covered by the semiconductor component. This arrangement can be utilized advantageously since electronic components, after their fabrication, are usually tested with regard to the correctness of their arrangement by an imaging test. Preferably, image recognition systems or X-ray transillumination are appropriate in this case. The preferred arrangement of the cutouts in the region at least partly covered by the semiconductor component is advantageous, insofar as that part of the cutout which is not covered by the assigned semiconductor component can serve for monitoring the proper arrangement of the cutouts by the imaging test.

The depth of the at least one cutout is preferably at least about 20 percent, at most 100 percent, of the depth of the electrically conductive film. The total cross-sectional area of all the cutouts assigned to a semiconductor component amounts to at most about 50 percent of the cross-sectional area of the assigned semiconductor component.

In the region of the electrically conductive film provided as power connection pad, the film is connected cohesively or in force-locking fashion to the at least one power semiconductor component, and the remaining volume may be filled with insulating material. The at least one cutout advantageously enables the filler to penetrate into the cutout, which significantly improves the anchoring strength of the insulating material on the electrically conductive film once cured.

In the region of the second electrically conductive film, the latter is connected to at least one driver component cohesively, preferably by adhesive bonding, wherein here as well the cutout enables infiltration of the adhesive material used (by way of example) and hence improved anchoring.

The process of conductor track structuring takes place by, for example, etching. What is advantageous in this case is that the cutouts can be produced during fabrication by structuring the conductor tracks on the electrically conductive film.

Particularly preferred developments of this arrangement are mentioned in the respective description of the exemplary embodiments. The inventive solution is additionally explained in more detail on the basis of the exemplary embodiments in FIGS. 1 to 4.

Other objects and features of the present invention will become apparent from the following detailed description considered in conjunction with the accompanying drawings. It is to be understood, however, that the drawings are designed solely for purposes of illustration and not as a definition of the limits of the invention, for which reference should be made to the appended claims. It should be further understood that the drawings are not necessarily drawn to scale and that, unless otherwise indicated, they are merely intended to conceptually illustrate the structures and procedures described herein.

### BRIEF DESCRIPTION OF THE DRAWINGS

In the drawings:

FIG. 1a is a cross-section of a first configuration of the inventive arrangement;

FIG. 1b is a detail of the portion of the arrangement of FIG. 1a shown by dotted box 1b;

FIG. 2 is a plan view of a first configuration of the inventive arrangement of power semiconductor elements on the structured conductor tracks of the electrically conductive film;

FIG. 3 is a plan view of a further configuration of the inventive arrangement of power semiconductor elements on the structured conductor tracks of the substrate;

FIG. 4 is a plan view of a still further configuration of the inventive arrangement of power semiconductor elements on the structured conductor tracks of the substrate.

### DETAILED DESCRIPTION OF THE PRESENTLY PREFERRED EMBODIMENTS

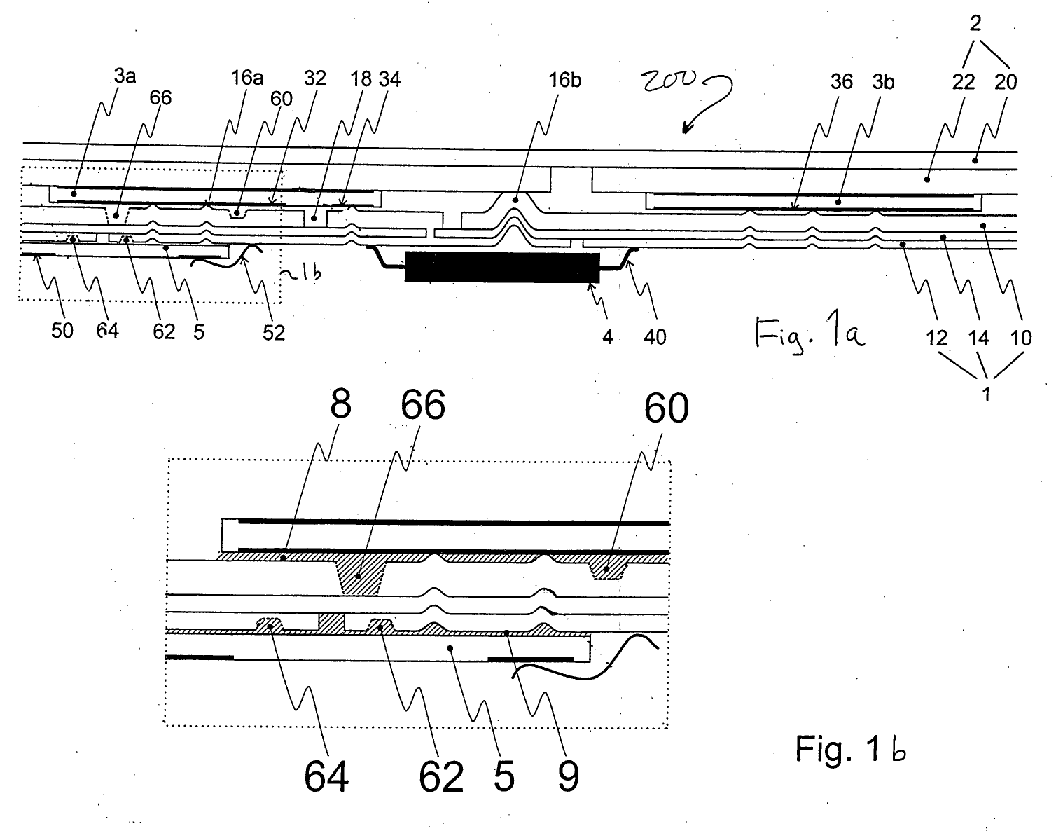

FIG. 1a shows the inventive connecting structure arrangement, generally at 200. Connecting structure 200 includes a connecting device 1 configured as a layered film composite 10, 12, 14 and components 3 a/b, 4, 5 shown in cross-section. FIG. 1b shows a detail of that portion of FIG. 1a designated by dotted box 1b. The film composite comprises at least one insulating film 14 disposed between first and second electrically conductive films 10, 12 (respectively). At least one conductive film is inherently structured 18 and thus forms conductor tracks 100, 120 that are insulated from one another.

The power semiconductor components 3a, 3b arranged on the conductor tracks 100, 120 of first electrically conductive film 10 are, by way of non-limiting examples only, a power diode 3b and a power transistor 3a. Power semiconductor components 3 have in each case at least one contact area 32 on their side facing connecting device 1. For electrically conductively connecting first electrically conductive film 10 to contact areas 32 of power semiconductor components 3 a/b, film composite 1 has first contact knobs 16a, b, for example. The volume between first electrically conductive film 10 and at least one power semiconductor component 3 a/b is filled with a low viscosity filler 8.

Semiconductor components 4, 5 arranged on the second electrically conductive film 12 are driver components, for example, and serve for controlling the power semiconductor component. Here they are fixed cohesively, preferably by adhesive bonding 9 and connected to further conductor tracks of second electrically conductive film 12 by thin wire bonding 52.

Cutouts 60, 62, 64, 66 are positioned at at least one location on at least one conductive film 10, 12 in a region at least partly covered by a semiconductor component 3/4/5. By way of example, some cutouts 60, 66 are cylindrical, and others 62, 64 with a cross-shaped cross-section (not able to be illustrated differentiably here in cross-section). Furthermore, some cutouts 60, 64 have a depth preferably amounting to 30 percent of the thickness of the electrically conductive film, and others 62, 66 extend completely thereof the electrically conductive film. The total cross-sectional area of all the cutouts 60 and 66, 62 and 64 assigned to a semiconductor component amounts here for example to about 20 percent, in any event at most about 50 percent, of the cross-sectional area of the assigned semiconductor component. The cross-sectional area of each individual cutout amounts in any event to at most about 25 percent of the cross-sectional area of the assigned semiconductor component.

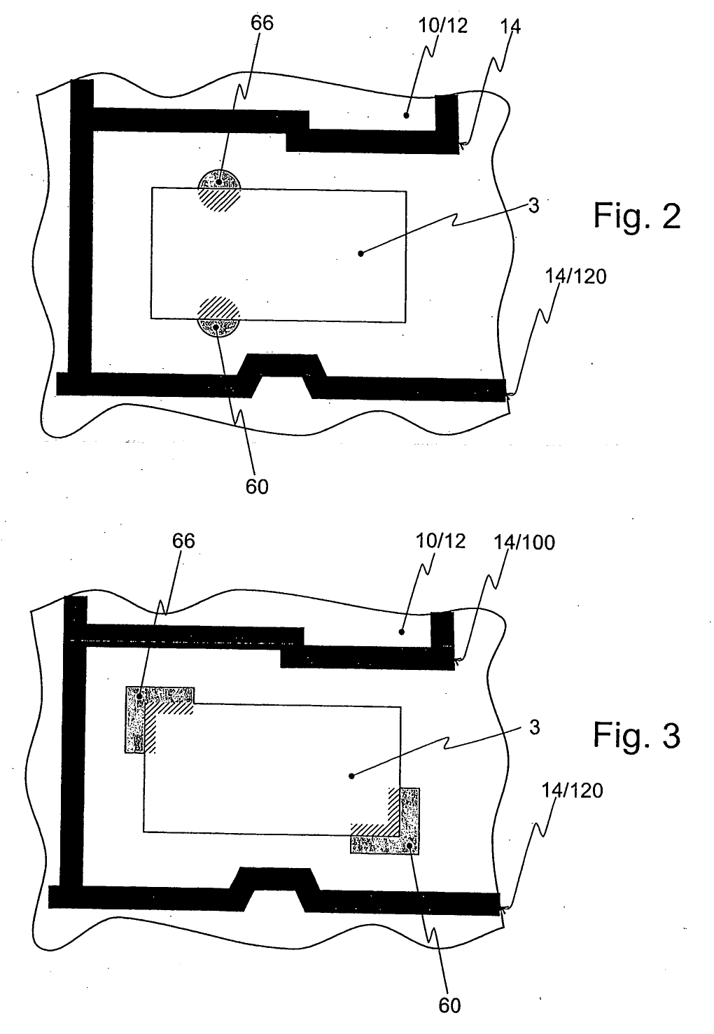

FIG. 2 shows a close-up plan view of the inventive connecting structure, wherein the three-layered construction described in FIG. 1 is likewise assumed. FIG. 2 shows an electrically conductive film 10, which is inherently structured 18 and thus here forms conductor tracks, and an insulating film 14 becoming visible in the structure tracks. The illustration furthermore shows a semiconductor component 3 and cutouts 60, 66 in a preferred arrangement in that the cutouts have a round cross-section (i.e. are generally cylindrical) and are situated at least with one segment section below semiconductor component 3, while a second segment section projects beyond semiconductor component 3.

FIG. 3 shows a further exemplary configuration of the inventive structure, wherein the cutouts 60, 66 are now configured with an L-shaped cross-section and project at least partly below and partly beyond semiconductor component 3.

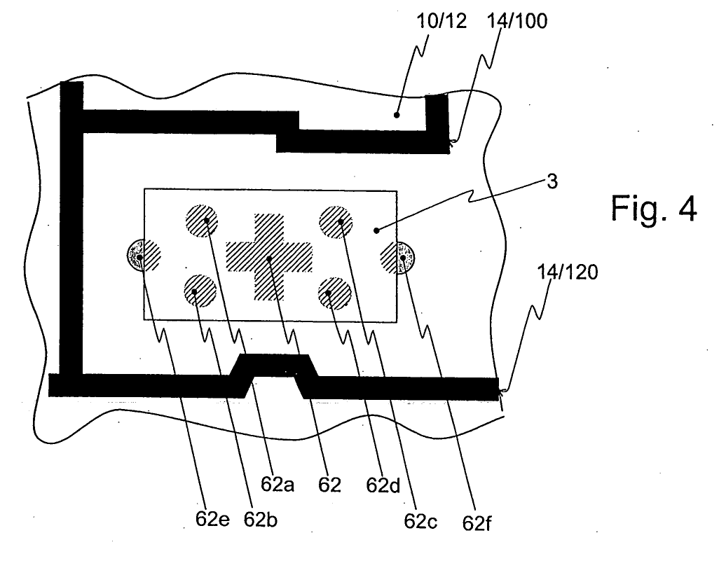

FIG. 4 shows a still further exemplary configuration of the inventive structure, wherein here, indicated schematically, one cutout 62 centrally and completely below assigned semiconductor component 3. Additionally, a plurality of cylindrical cutouts 62 a-f are also arranged around centrally disposed cutout 62, wherein some cutouts 62 a-d lie completely below the area assigned to the semiconductor component and others 62 e, f project visibly with a segment section below semiconductor component 3. The total cross-sectional area of all the cutouts is preferably less that about one-half the total cross-sectional area of the semiconductor component to be disposed therein.

Thus, while there have shown and described and pointed out fundamental novel features of the invention as applied to a preferred embodiment thereof, it will be understood that various omissions and substitutions and changes in the form and details of the devices illustrated, and in their operation, may be made by those skilled in the art without departing from the spirit of the invention. For example, it is expressly intended that all combinations of those elements and/or method steps which perform substantially the same function in substantially the same way to achieve the same results are within the scope of the invention. Moreover, it should be recognized that structures and/or elements and/or method steps shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

What is claimed is:

1. A connecting structure for connecting at least one semiconductor component to a power semiconductor module, the connecting structure comprising:
a connecting device including:
first and second electrically conductive films; and
an insulating film disposed between said first and second electrically conductive films;
at least one of said first and second electrically conductive films having a cutout disposed therein, said cutout:
being positioned in said at least one of said first and second electrically conductive films so as to be at least partly covered by an assigned semiconductor component; and
having a cross-sectional area of no more than about 25% of the cross-sectional area of the assigned semiconductor component; and
a filler disposed between said connecting device and the at least one semiconductor component.

2. The connecting structure of claim 1, wherein at least one of said first and second electrically conductive films is configured to form at least one conductor track.

3. The connecting structure of claim 1, wherein the assigned semiconductor component is a power semiconductor component.

4. The connecting structure of claim 3, wherein
at least one of said first and second electrically conductive films includes a knob; and
the power semiconductor component is electrically conductively connected to said knob.

5. The connecting structure of claim 4, wherein the power semiconductor component is cohesively connected to said knob.

6. The connecting structure of claim 4, wherein the power semiconductor component is connected to said knob by a force locking connection.

7. The connecting structure of claim 1, wherein the assigned semiconductor component is a driver component.

8. The connecting structure of claim 7, wherein the driver component is connected to one of said first and second electrically conductive films by a cohesive adhesive connection.

9. The connecting structure of claim 1, wherein said cutout is cylindrical.

10. The connecting structure of claim 1, wherein said cutout has an L-shaped cross-section.

11. The connecting structure of claim 1, wherein said cutout has a cross-shaped cross-section.

12. The connecting structure of claim 1, wherein said cutout is disposed to be less than completely covered by the assigned semiconductor component.

13. The connecting structure of claim 1, wherein said cutout is disposed to be substantially completely covered by the assigned semiconductor component.

14. The connecting structure of claim 13, wherein said cutout is disposed generally centrally to the assigned semiconductor component.

15. The connecting structure of claim 1, wherein said cutout has a depth of at least about 20% of the thickness of said at least one of said first and second electrically conductive films.

16. The connecting structure of claim 1, further comprising a plurality of cutouts positioned in said at least one of said first and second electrically conductive films so as to be at least partly covered by the assigned semiconductor component, and wherein the total cross-sectional area of said plurality of said cutouts is no more than about one-half of the total cross-sectional area of the assigned semiconductor component.
